(19) United States
(12) Patent Application Publication
(10) Pub. No.: US 2018/0301529 A1
(43) Pub. Date: Oct. 18, 2018

(54) SEMICONDUCTOR DEVICE AND METHOD FOR MANUFACTURING SAME

(71) Applicant: Kabushiki Kaisha Toshiba, Minato-ku (JP)

(72) Inventor: Takuo KIKUCHI, Kamakura (JP)

(73) Assignee: Kabushiki Kaisha Toshiba, Minato-ku (JP)

(21) Appl. No.: 15/855,141

(22) Filed: Dec. 27, 2017

(30) Foreign Application Priority Data
Apr. 14, 2017 (JP) 2017-080321

(51) Int. Cl. H01L 29/06; H01L 29/78; H01L 29/10; H01L 29/66; H01L 21/3065; H01L 21/02

(52) U.S. Cl. CPC H01L 29/0634; H01L 29/7802; H01L 29/1095; H01L 29/16; H01L 21/3065; H01L 21/02532; H01L 21/0257; H01L 29/66712

(57) ABSTRACT

A semiconductor device includes a first semiconductor layer of a first conductivity type having a first surface crossing a first direction; a first semiconductor region of a second conductivity type provided in the first semiconductor layer, and including first and second layers aligned in the first direction; a second semiconductor region of the second conductivity type electrically connected to the first semiconductor region, and having a portion provided between the first surface and the first semiconductor region; and a third semiconductor region of the first conductivity type having a portion provided between the first surface and the portion of the second semiconductor region. The semiconductor device further includes a control electrode provided on the second semiconductor region via a first insulating film; an electrode electrically connected to the second and third semiconductor regions; and a sidewall region provided between the first semiconductor region and the first semiconductor layer.

### CROSS-REFERENCE TO RELATED APPLICATIONS

This application is based upon and claims the benefit of priority from Japanese Patent Application No. 2017-080321, filed on Apr. 14, 2017; the entire contents of which are incorporated herein by reference.

### FIELD

Embodiments generally relate to a semiconductor device and a method for manufacturing the same.

### BACKGROUND

A semiconductor device, such as a super junction MOSFET, includes an n-type drift layer configured to be depleted at a low voltage so that the electric field strength becomes uniform in the n-type drift layer when applying a high voltage. Thereby, a high breakdown voltage is achieved. In such a semiconductor device, it is desirable to suppress abrupt changes of the capacitance.

### BRIEF DESCRIPTION OF THE DRAWINGS

FIG. 1 is a schematic cross-sectional view illustrating a semiconductor device according to a first embodiment;

FIG. 2 is a schematic view showing a relationship between a drain voltage and a drain-source capacitance according to a reference example;

FIG. 3 is a schematic view showing a relationship between a drain-source capacitance and a drain voltage according to the first embodiment;

FIGS. 4A to 4H are schematic cross-sectional views illustrating one manufacturing method of the semiconductor device according to the first embodiment;

FIG. 5 is a schematic cross-sectional view showing the semiconductor device fabricated by the one manufacturing method;

FIG. 6 is a schematic cross-sectional view illustrating a semiconductor device according to a second embodiment;

FIGS. 7A and 7B are schematic cross-sectional views illustrating one manufacturing method of the semiconductor device according to the second embodiment;

FIG. 8 is a schematic cross-sectional view illustrating a semiconductor device according to a third embodiment;

FIGS. 9A to 9C are schematic cross-sectional views illustrating one manufacturing method of the semiconductor device according to the third embodiment; and

FIGS. 10A to 10E are schematic cross-sectional views illustrating a manufacturing method of a semiconductor device according to a fourth embodiment.

### DETAILED DESCRIPTION

According to one embodiment, a semiconductor device includes a first semiconductor layer of a first conductivity type having a first surface and a second surface, the first surface and the second surface crossing a first direction aligned with a direction from the second surface toward the first surface; a first semiconductor region of a second conductivity type provided in the first semiconductor layer, the first semiconductor region including a first layer of the second conductivity type, and a second layer of the second conductivity type, a direction from the first layer toward the second layer being aligned with the first direction, and an impurity concentration of the second conductivity type in the second layer being different from an impurity concentration of the second conductivity type in the first layer; a second semiconductor region of the second conductivity type electrically connected to the first semiconductor region, at least a portion of the second semiconductor region being provided at a position in the first direction between a position in the first direction of the first surface and a position in the first direction of the first semiconductor region; and a third semiconductor region of the first conductivity type, at least a portion of the third semiconductor region being provided at a position in the first direction between the position in the first direction of the first surface and the position in the first direction of the at least a portion of the second semiconductor region. The semiconductor device further includes a control electrode; a first insulating film provided between the control electrode and the second semiconductor region; a first electrode electrically connected to the first semiconductor layer; a second electrode electrically connected to the second semiconductor region and the third semiconductor region; and a sidewall region provided between the first semiconductor region and the first semiconductor layer.

Embodiments of the invention will now be described with reference to the drawings.

The drawings are schematic or conceptual; and the relationship between a thickness and a width in each portion, the proportions of sizes between portions, etc., are not necessarily the same as the actual values thereof. There are also cases where the dimensions and/or the proportions are illustrated differently between the drawings, even in the case where the same portion is illustrated.

In the specification and each drawing, components similar to ones described in reference to an antecedent drawing are marked with the same reference numerals, and a detailed description is omitted as appropriate.

### First Embodiment

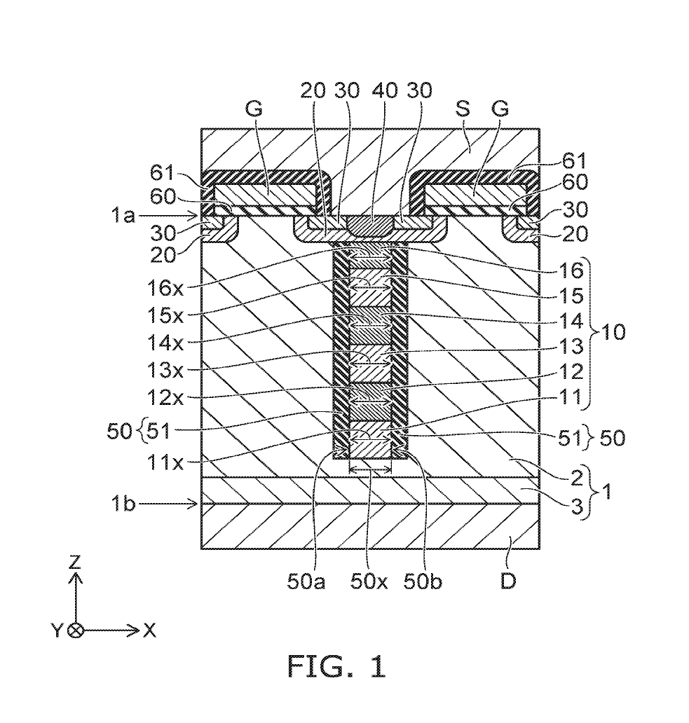

FIG. 1 is a schematic cross-sectional view illustrating a semiconductor device according to a first embodiment. A first direction, a second direction, and a third direction are shown in FIG. 1. In the specification, the first direction is taken as a Z-axis direction. One direction that crosses, e.g., is orthogonal to, the Z-axis direction is taken as the second direction. The second direction is an X-axis direction. One direction that crosses, e.g., is orthogonal to, the Z-axis direction and the X-axis direction is taken as the third direction. The third direction is a Y-axis direction. In the first embodiment, the semiconductor is, for example, silicon (Si). Alternatively, it is also possible to use a semiconductor other than Si. Si may include carbon (C).

As shown in FIG. 1, the semiconductor device according to the first embodiment includes a first semiconductor layer 1 of a first conductivity type, a first semiconductor region 10 of a second conductivity type, a second semiconductor region 20 of the second conductivity type, and a third semiconductor region 30 of the first conductivity type. The semiconductor device also includes a control electrode G, a first insulating film 60, a first electrode D, a second electrode S, and a sidewall region 50.

In the Z-axis direction, the first semiconductor layer 1 has a first surface 1a and a second surface 1b that cross the Z-axis direction. The direction from the second surface 1b toward the first surface 1a is aligned with the Z-axis direction. The first semiconductor layer 1 is, for example, an n-type drain region. The first semiconductor layer 1 includes a low-concentration n-type drain layer 2 and a high-concentration n⁺-type drain layer 3. The concentration of the n-type impurity of the high-concentration n⁺-type drain layer 3 is higher than the n-type impurity concentration of the low-concentration n-type drain layer 2. The low-concentration n-type drain layer 2 is provided on the first surface 1a side of the first semiconductor layer 1. The high-concentration n⁺-type drain layer 3 is provided on the second surface 1b side of the first semiconductor layer 1. The low-concentration n-type drain layer 2 is provided on the high-concentration n⁺-type drain layer 3. The low-concentration n-type drain layer 2 contacts the high-concentration n⁺-type drain layer 3. For example, the low-concentration n-type drain layer 2 is an n-type drift layer.

The first semiconductor region 10 is provided inside the first semiconductor layer 1 along the Z-axis direction. The first semiconductor region 10 is, for example, a p-type pillar region. The first semiconductor region 10 includes a first layer 11 of the second conductivity type and a second layer 12 of the second conductivity type along the Z-axis direction. In the embodiment, the conductivity type of the first layer 11 and the conductivity type of the second layer 12 each are the p-type. The p-type impurity concentration of the second layer 12 is different from that of the first layer 11. The p-type impurity concentration of the second layer 12 may be higher or lower than the p-type impurity concentration of the first layer 11. It is sufficient for a difference of impurity concentrations to exist between the p-type impurity concentration of the second layer 12 and the p-type impurity concentration of the first layer 11.

It is sufficient for the first semiconductor region 10 to include at least the first layer 11 and the second layer 12. For example, the first semiconductor region 10 of the embodiment further includes a third layer 13, a fourth layer 14, a fifth layer 15, and a sixth layer 16. The conductivity types of the third to sixth layers 13 to 16 each are the second conductivity type. The p-type impurity concentrations of the third layer 13 and the fifth layer 15 are, for example, equal to the p-type impurity concentration of the first layer 11. The p-type impurity concentrations of the fourth layer 14 and the sixth layer 16 are, for example, equal to the impurity concentration of the second layer 12. However, the p-type impurity concentrations of the first to sixth layers 11 to 16 are not limited thereto. For example, the p-type impurity concentrations of the first to sixth layers 11 to 16 may be higher in order from the second surface 1b side of the first semiconductor layer 1 toward the first surface 1a in the Z-axis direction. Conversely, the p-type impurity concentrations of the first to sixth layers 11 to 16 may be lower in order from the second surface 1b side of the first semiconductor layer 1 toward the first surface 1a in the Z-axis direction. Various other p-type impurity concentration settings are possible for the first to sixth layers 11 to 16. Seven or more layers may be provided in the first semiconductor region 10. The number of layers is arbitrary.

The sidewall region 50 is provided between the first semiconductor region 10 and the first semiconductor layer 1, and extends along the Z-axis direction. The sidewall region 50 includes, for example, an insulating body 51. One example of the insulating body 51 is, for example, silicon oxide. The insulating body 51 is not limited to silicon oxide. In the cross section shown in FIG. 1, the insulating body 51 of the sidewall region 50 has a first side surface 50a and a second side surface 50b. The first side surface 50a of the insulating body 51 and the second side surface 50b of the insulating body 51 each contact the first semiconductor region 10. In the cross section shown in FIG. 1, the first semiconductor region 10 is between the first side surface 50a of the insulating body 51 and the second side surface 50b of the insulating body 51. Widths 11x to 16x, i.e., a width 11x in the X-axis direction of the first layer 11, a width 12x in the X-axis direction of the second layer 12, . . . , and a width 16x in the X-axis direction of the sixth layer each are determined by, for example, a distance 50x between the first side surface 50a of the insulating body 51 and the second side surface 50b of the insulating body 51. Therefore, for example, the “fluctuation of the dimensions” of the width 11x in the X-axis direction of the first layer 11, the width 12x in the X-axis direction of the second layer 12, . . . , and the width 16x in the X-axis direction of the sixth layer 16 can be suppressed to be small. The positions of the first to sixth layers 11 to 16 are determined self-aligningly between the first side surface 50a of the insulating body 51 and the second side surface 50b of the insulating body 51. “Positional shift” of the first to sixth layers 11 to 16 does not occur easily.

The second semiconductor region 20 is provided in the first semiconductor layer 1 from the first surface 1a of the first semiconductor layer 1. The second semiconductor region 20 is electrically connected to the first semiconductor region 10. The second semiconductor region 20 is, for example, a p-type base region. For example, the position of at least a portion of the second semiconductor region 20 in the Z-axis direction is between the position of the first surface 1a in the Z-axis direction and the position of the first semiconductor region 10 in the Z-axis direction.

The third semiconductor region 30 is provided in the second semiconductor region 20 from the first surface 1a of the first semiconductor layer 1. The third semiconductor region 30 is, for example, an n-type source region. The position of at least a portion of the third semiconductor region 30 in the Z-axis direction is between the position of the first surface 1a in the Z-axis direction and the position of at least a portion of the second semiconductor region 20 in the Z-axis direction.

The control electrode G is provided on the second semiconductor region 20 between the first semiconductor layer 1 and the third semiconductor region 30. The control electrode G is, for example, a gate electrode.

The first insulating film 60 is provided between the control electrode G and the second semiconductor region 20. The first insulating film 60 is, for example, a gate insulating film. A second insulating film 61 is provided on the control electrode G. The second insulating film 61 is, for example, an inter-layer insulating film.

The first electrode D is electrically connected to the first semiconductor layer 1. The first electrode D is, for example, a drain electrode.

The second electrode S is electrically connected to the third semiconductor region 30. The second electrode S is electrically connected to the second semiconductor region 20 via a fourth semiconductor region 40 of the second conductivity type. The second electrode S is, for example, a source electrode. The fourth semiconductor region 40 is provided in the second semiconductor region 20 and the third semiconductor region 30 from the first surface 1a of the first semiconductor layer 1. For example, the position of the fourth semiconductor region 40 in the Z-axis direction is between the position of the first surface 1a in the Z-axis direction and the position of the first semiconductor region 10 in the Z-axis direction. The p-type impurity concentration of the fourth semiconductor region 40 is, for example, higher than the p-type impurity concentration of the second semiconductor region 20. The fourth semiconductor region 40 is, for example, a high-concentration p-type contact layer.

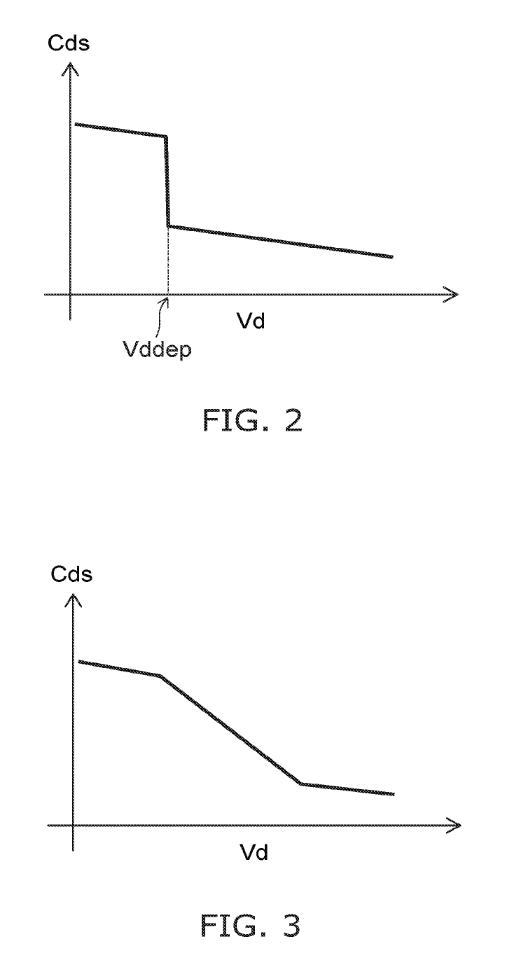

FIG. 2 is a schematic view showing the relationship between a drain voltage Vd and a drain-source capacitance Cds according to a reference example. FIG. 3 is a schematic view showing the relationship between a drain voltage and a drain-source capacitance according to the first embodiment. The reference example is the case where there is no difference in the concentration of the p-type impurity of the first semiconductor region 10. In the reference example as shown in FIG. 2, when the drain voltage Vd reaches a voltage Vddep, the drain-source capacitance Cds changes abruptly, e.g., decreases abruptly. This is because the first semiconductor region 10 and the low-concentration n-type drain layer 2 (the n-type drift layer) deplete all at once when the drain voltage Vd reaches the voltage Vddep.

In the first embodiment as shown in FIG. 3, the drain-source capacitance Cds does not decrease abruptly compared to the reference example. In the first embodiment, the drain-source capacitance Cds decreases gradually as the drain voltage Vd increases. This is because the first semiconductor region 10 includes at least the two layers of the first layer 11 and the second layer 12 that have different concentrations of the p-type impurity. In the first semiconductor region 10 of the semiconductor device according to the first embodiment, for example, the first to sixth layers 11 to 16 deplete from the layers having low concentrations of the p-type impurity. The depletion progresses toward the layers having high concentrations of the p-type impurity. According to the semiconductor device of the first embodiment, the abrupt change of the drain-source capacitance Cds can be suppressed.

In the first embodiment, the sidewall region 50 is provided between the first semiconductor region 10 and the first semiconductor layer 1. In the first semiconductor region 10, for example, the width 11x in the X-axis direction of the first layer 11 to the width 16x in the X-axis direction of the sixth layer 16 each can be determined by the distance 50x between the first side surface 50a of the sidewall region 50 and the second side surface 50b of the sidewall region 50. The “fluctuation of the dimensions” can be suppressed to be small for each of such first to sixth layers 11 to 16. If the “fluctuation of the dimensions” can be small, the “fluctuation of the capacitance” between, for example, the low-concentration n-type drain layer 2 of the first semiconductor layer 1 and each of the first to sixth layers 11 to 16 can be suppressed to be small. According to the semiconductor device of the first embodiment, for example, a semiconductor device can be obtained in which the “fluctuation of the characteristics” between devices is small and the quality is more uniform between devices.

The positions of the first to sixth layers 11 to 16 are determined self-aligningly between the first side surface 50a of the insulating body 51 and the second side surface 50b of the insulating body 51. “Positional shift” of the first to sixth layers 11 to 16 does not occur easily. From this perspective as well, according to the semiconductor device of the first embodiment, the quality can be more uniform between devices.

For example, by manufacturing the semiconductor device according to the first embodiment by using the manufacturing method described below, the semiconductor device according to the first embodiment can be manufactured while suppressing an increase of the number of manufacturing processes.

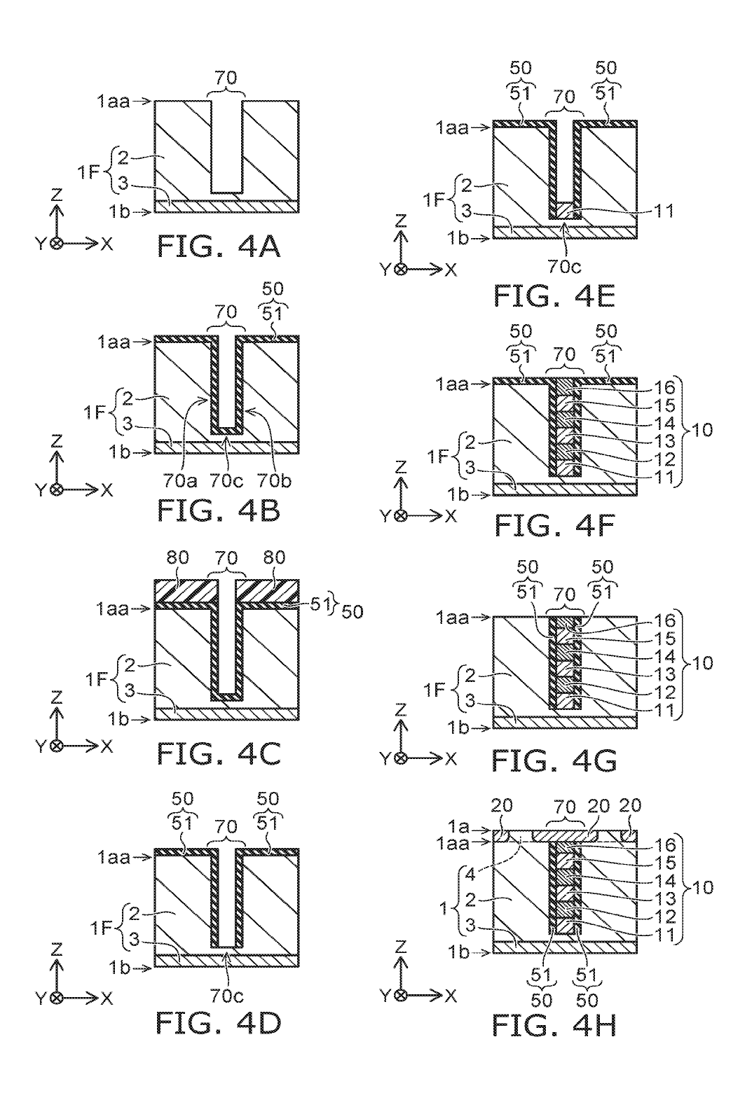

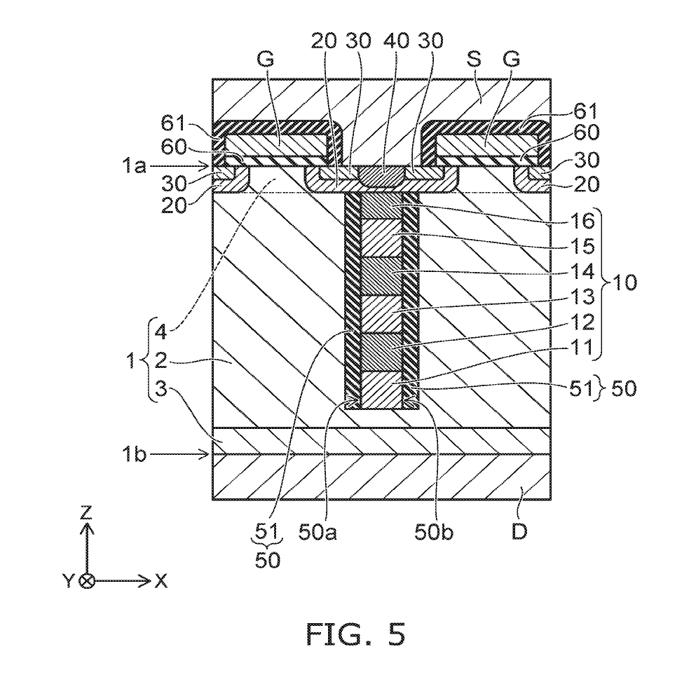

FIG. 4A to FIG. 4H are schematic cross-sectional views illustrating one method for manufacturing the semiconductor device according to the first embodiment. FIG. 5 is a schematic cross-sectional view showing the semiconductor device manufactured according to the one manufacturing method.

As shown in FIG. 4A, a trench 70 is formed in a first semiconductor film 1F having a surface 1aa and the second surface 1b crossing the Z-axis direction. The first semiconductor film 1F is used to form a portion of the first semiconductor layer 1. The direction from the second surface 1b toward the surface 1aa is aligned with the Z-axis direction. The trench 70 is formed in the surface 1aa. In the example, the first semiconductor layer 1 (the first semiconductor film 1F) includes the low-concentration n-type drain layer 2 and the high-concentration n⁺-type drain layer 3. The high-concentration n⁺-type drain layer 3 is provided on the second surface 1b side of the first semiconductor layer 1 (the first semiconductor film 1F). The low-concentration n-type drain layer 2 is provided on the high-concentration n⁺-type drain layer 3. The low-concentration n-type drain layer 2 contacts the high-concentration n⁺-type drain layer 3.

Then, the sidewall region 50 that includes the insulating body 51 is formed on a side surface 70a of the trench 70. In the example as shown in FIG. 4B, the sidewall region 50 that includes the insulating body 51 is formed on the surface 1aa of the first semiconductor film 1F, on the first side surface 70a of the trench 70, on a second side surface 70b of the trench 70, and on a bottom surface 70c of the trench 70. The insulating body 51 is, for example, silicon oxide. In the case where the insulating body 51 is, for example, silicon oxide, the insulating body 51 may be formed by thermal oxidation of the first semiconductor film 1F or by, for example, depositing silicon oxide by CVD.

Then, as shown in FIG. 4C, a mask member 80 is formed, with the sidewall region 50 including the insulating body 51 interposed, in a portion on the surface 1aa of the first semiconductor film 1F. The mask member 80 is, for example, a photoresist layer.

Subsequently as shown in FIG. 4D, the insulating body 51 that is on the bottom surface 70c of the trench 70 is removed using the mask member 80 as a mask. Then, the mask member 80 that is on the sidewall region 50 including the insulating body 51 is removed.

By using selective epitaxial growth, the first semiconductor region 10 is formed in the trench 70. The first semiconductor region includes at least the first layer 11 of the second conductivity type and the second layer 12 of the second conductivity type that is different in an impurity concentration of the second conductivity type from the first layer. In the example as shown in FIG. 4E, the first layer 11 is formed on the bottom surface 70c of the trench 70 by using selective epitaxial growth. The first layer 11 is, for example, p-type Si. The p-type Si is formed by, for example, introducing a gas including Si and a gas including a p-type impurity, e.g., boron, into a processing chamber of a film formation apparatus (not illustrated). The insulating body 51 is, for example, silicon oxide. A portion of the bottom surface 70c of the trench 70 is Si, e.g., n-type Si. The first layer 11 is formed, for example, under the film formation condition where the growth rate of the p-type Si is different on the Si (e.g., the n-type Si) and on the silicon oxide. For example, the first layer 11 is formed under the film formation condition where the growth rate of the p-type Si is fast on Si (e.g., n-type Si), and slow on silicon oxide. Alternatively, a first layer 11 is formed under the film formation condition where the p-type Si is not grown on the silicon oxide. Thereby, the first layer 11 can be epitaxially grown selectively on, for example, the n-type Si. In the specification, such a film formation method is referred to as selective epitaxial growth.

Then, as shown in FIG. 4F, the second layer 12 is formed on the first layer 11 by using the selective epitaxial growth. The second layer 12 is, for example, p-type Si. When forming the second layer 12, the flow rate of the gas including the p-type impurity, e.g., boron, in the processing chamber (not illustrated) is different from that when forming the first layer 11. Thereby, the second layer 12 can be epitaxially grown selectively on the first layer 11 so that the second layer 12 is different in the p-type impurity concentration from the first layer 11. Then, the third to sixth layers 13 to 16 are formed similarly to the first layer 11 and the second layer 12 by using the selective epitaxial growth and by controlling the flow rate of the gas including, for example, boron so that the p-type impurity concentrations of the third to sixth layers 13 to 16 have the designed values. Thereby, the first semiconductor region 10 that includes at least the first layer 11 and the second layer 12 is formed inside the trench 70. In the example, the first semiconductor region 10 includes the first to sixth layers 11 to 16.

Then, the second semiconductor region 20 of the second conductivity type is formed in the first semiconductor film 1F from the surface 1aa of the first semiconductor film 1F so that the second semiconductor region 20 is electrically connected to the first semiconductor region 10. In the example as shown in FIG. 4G, for example, parts of the sixth layer 16 and the sidewall region 50 including the insulating body 51 are chemically and mechanically polished, which are provided above a level of the surface 1aa of the first semiconductor film 1F. Thereby, the part of the sidewall region 50 is removed, which includes the insulating body 51 and is on the surface 1aa of the first semiconductor film 1F. Then, as shown in FIG. 4H, for example, a second semiconductor layer (a semiconductor partial region 4) of the first conductivity type is formed on the surface 1aa of the first semiconductor film 1F, on the sixth layer 16 of the first semiconductor region 10, and on the insulating body 51 of the sidewall region 50. The conductivity type of the second semiconductor layer (the semiconductor partial region 4) is, for example, the n-type. The second semiconductor layer (the semiconductor partial region 4) is, for example, an n-type epitaxial layer. For example, CVD is used to form the second semiconductor layer. The first semiconductor layer 1 is formed by forming the second semiconductor layer (the semiconductor partial region 4). The first semiconductor layer 1 includes the low-concentration n-type drain layer 2, the high-concentration n⁺-type drain layer 3, and the second semiconductor layer (the semiconductor partial region 4). The surface of the second semiconductor layer (the semiconductor partial region 4) is the first surface 1a of the first semiconductor layer 1. Then, the second semiconductor region 20 of the second conductivity type is formed from the first surface 1a of the first semiconductor layer 1 inside the first semiconductor layer 1, e.g., in the second semiconductor layer (the semiconductor partial region 4). The second semiconductor region 20 contacts the first semiconductor region 10 so as to be electrically connected to the first semiconductor region 10.

Subsequently, the first insulating film 60, the control electrode G, the third semiconductor region 30, the first electrode D, the second insulating film 61, and the second electrode S are formed according to well-known manufacturing methods. In the example as shown in FIG. 5, for example, the first insulating film 60 is formed on the first surface 1a of the first semiconductor layer 1 by using, for example, thermal oxidation. Thereby, the first insulating film 60 is formed on the second semiconductor region 20. Then, a conductor is formed on the first insulating film 60. Continuing, the control electrode G is formed by patterning the conductor and the first insulating film 60. Then, for example, an impurity of the first conductivity type is introduced to the second semiconductor region 20 using the control electrode G as a mask. Thereby, the third semiconductor region 30 of the first conductivity type is formed in the second semiconductor region 20. Then, the second insulating film 61 is formed on the control electrode G. Continuing, the fourth semiconductor region 40 of the second conductivity type is formed from the first surface 1a of the first semiconductor layer 1 into the third semiconductor region 30 and the second semiconductor region 20. Then, the first electrode D that is electrically connected to the first semiconductor layer 1 is formed; and the second electrode S is formed so as to be electrically connected to the second semiconductor region 20 and the third semiconductor region 30.

Thus, the semiconductor device according to the first embodiment such as that shown in FIG. 5 can be manufactured. The first semiconductor layer 1 includes the second semiconductor layer (the semiconductor partial region 4) in the semiconductor device shown in FIG. 5. The second semiconductor layer (the semiconductor partial region 4) is of the first conductivity type and is included in the first semiconductor layer 1 of the first conductivity type. The second semiconductor layer (the semiconductor partial region 4) overlaps the second semiconductor region 20 and the third semiconductor region 30 in a direction crossing the Z-axis direction (e.g., the X-axis direction). Thus, in the semiconductor device according to the first embodiment, the first semiconductor layer 1 may include, for example, the low-concentration n-type drain layer 2, the high-concentration n⁺-type drain layer 3, and the second semiconductor layer (the semiconductor partial region 4). The second semiconductor layer (the semiconductor partial region 4) is, for example, an n-type epitaxial layer. The second semiconductor layer (the semiconductor partial region 4) is provided on the first surface 1a side of the first semiconductor layer 1. The second semiconductor layer (the semiconductor partial region 4) is provided on, for example, the low-concentration n-type drain layer 2 and contacts, for example, the low-concentration n-type drain layer 2. For example, the second semiconductor region is provided in the second semiconductor layer (the semiconductor partial region 4).

According to such a manufacturing method, for example, the first to sixth layers 11 to 16 are formed using the selective epitaxial growth. Therefore, the semiconductor device according to the first embodiment can be manufactured while suppressing the increase of the number of manufacturing processes.

The first to sixth layers 11 to 16 can be formed without unloading the semiconductor device, which is in the manufacturing process, from the processing chamber (not illustrated) of the film formation apparatus. Therefore, the throughput is improved in the manufacturing process of the semiconductor device.

For example, a case may be assumed where the low-concentration n-type drain layer 2 is divided into multiple layers, e.g., six layers, and the first to sixth layers 11 to 16 are formed one by one using ion implantation with different dose amount of the p-type impurity. In such a case, the film formation process, the PEP (Photo Engraving Process), the ion implantation process, the resist ashing process, and the cleaning process are repeated. For example, the semiconductor device under the manufacturing processes must be repeatedly loaded into and unloaded from the semiconductor manufacturing apparatuses such as a film formation apparatus, a resist coating apparatus, an exposure apparatus, a development apparatus, an ion implantation apparatus, an ashing apparatus, a cleaning apparatus, etc. Thus, the throughput easily decreases in the manufacturing processes of the semiconductor device, since the semiconductor device under the manufacturing process is conveyed many times.

According to the manufacturing method recited above, the first to sixth layers 11 to 16 can be formed inside the processing chamber (not illustrated) of the film formation apparatus. For example, the number of times for loading the semiconductor device, which is under the manufacturing, into the semiconductor manufacturing apparatuses and unloading it therefrom can be reduced in the manufacturing processes. Accordingly, the throughput of the semiconductor device can be improved.

### Second Embodiment

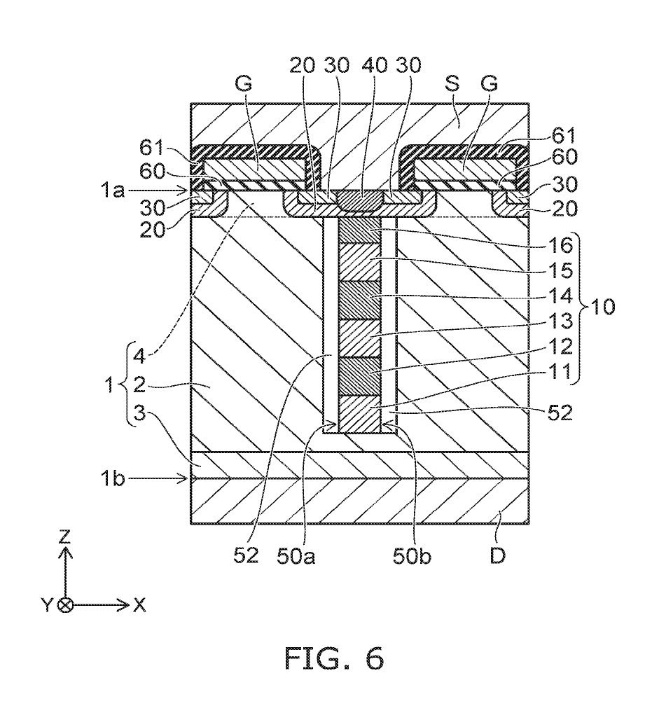

FIG. 6 is a schematic cross-sectional view illustrating a semiconductor device according to a second embodiment.

As shown in FIG. 6, the semiconductor device according to the second embodiment differs from the semiconductor device according to the first embodiment in that a gap 52 (e.g., a space) is provided instead of the sidewall region 50. The gap 52 is provided along the Z-axis direction between the first semiconductor region 10 and the first semiconductor layer 1. The gap 52 is between the first semiconductor region 10 and the first semiconductor layer 1 in a direction crossing the Z-axis direction. In the example, the gap 52 is provided between the low-concentration n-type drain layer 2 of the first semiconductor layer 1 and the first semiconductor region 10 including at least the first layer 11 and the second layer 12 along the Z-axis direction. For example, the gap 52 functions as an insulating body.

In the case where the gap 52 is provided, the first semiconductor layer 1 is manufactured, for example, such as follows.

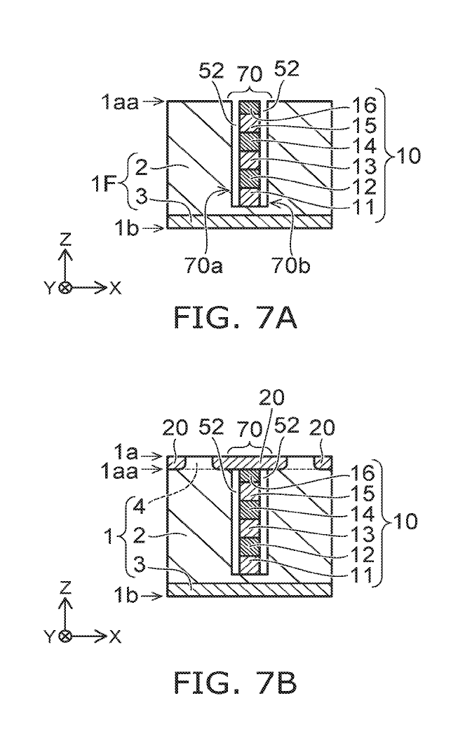

FIG. 7A to FIG. 7B are schematic cross-sectional views illustrating one method for manufacturing the semiconductor device according to the second embodiment.

A first semiconductor region 10 is formed inside the trench 70 by using the selective epitaxial growth according to the one example of the method for manufacturing the semiconductor device of the first embodiment described above, so that the first semiconductor region 10 includes at least a first layer 11 of the second conductivity type and a second layer 12 of the second conductivity type that is different in an impurity concentration of the second conductivity type from the first layer 11.

Then, as shown in FIG. 7A, the insulating body 51 is removed from the trench 70. Thereby, the gap 52 is formed between the first semiconductor region 10 and the first semiconductor film 1F. For example, the gap 52 is aligned with the Z-axis direction. For example, the removal of the insulating body 51 may be performed after forming the first semiconductor region 10 including, for example, the first to sixth layers 11 to 16 as shown in FIG. 4F or may be performed after, for example, the chemical mechanical polishing of the sixth layer 16 and the sidewall region 50 including the insulating body 51 as shown in FIG. 4G.

Then, as shown in FIG. 7B, the second semiconductor layer (the semiconductor partial region 4) of the first conductivity type is formed on the surface 1aa of the first semiconductor film 1F, on the sixth layer 16 of the first semiconductor region 10, and on the gap 52 under the film formation condition where the interior of the gap 52 is not filled completely, for example. Thereby, the first semiconductor layer 1 is formed. The first surface 1a of the first semiconductor layer 1 corresponds to the surface of the second semiconductor layer. The second semiconductor region 20 of the second conductivity type is formed inside the second semiconductor layer (the semiconductor partial region 4) from the first surface 1a of the first semiconductor layer 1. The second semiconductor region 20 contacts the first semiconductor region 10 so as to be electrically connected to the first semiconductor region 10.

Thereafter, the first insulating film 60, the control electrode G, the second insulating film 61, the third semiconductor region 30, the first electrode D, and the second electrode S are formed according to the one example of the method for manufacturing the semiconductor device according to the first embodiment described above.

As in the semiconductor device according to the second embodiment, the gap 52 along the Z-axis direction may be included instead of the sidewall region 50 between the first semiconductor region 10 and the first semiconductor layer 1. In the semiconductor device according to the second embodiment, for example, the breakdown voltage can be improved further because the gap 52 exists along the Z-axis direction between the first semiconductor region 10 and the first semiconductor layer 1.

### Third Embodiment

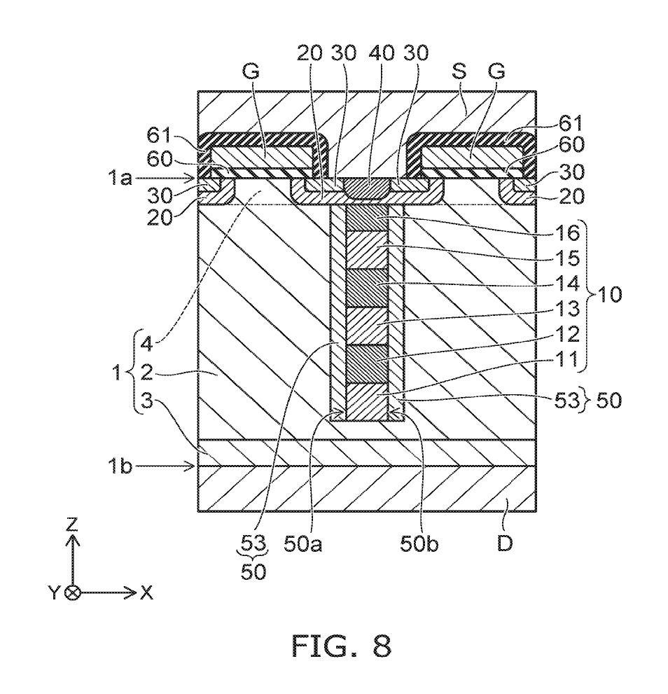

FIG. 8 is a schematic cross-sectional view illustrating a semiconductor device according to a third embodiment.

As shown in FIG. 8, the semiconductor device according to the third embodiment differs from the semiconductor device according to the first embodiment in that the sidewall region 50 includes a semiconductor 53 instead of the insulating body 51. The semiconductor 53 may be of the n-type or the p-type.

In the case where the sidewall region 50 that includes the semiconductor 53 is provided, the first semiconductor layer 1 is manufactured, for example, as follows.

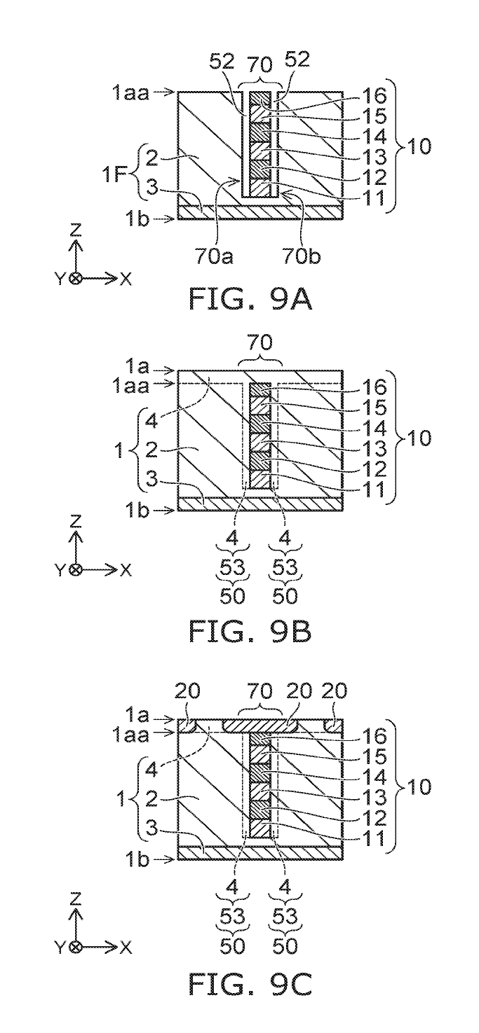

FIG. 9A to FIG. 9C are schematic cross-sectional views illustrating one method for manufacturing the semiconductor device according to the third embodiment.

A first semiconductor region 10 is formed in the trench 70 by using the selective epitaxial growth according to the one example of the method for manufacturing the semiconductor device of the first embodiment described above, so that the first semiconductor region 10 includes at least a first layer 11 of the second conductivity type and a second layer 12 of the second conductivity type that is different in an impurity concentration of the second conductivity type from the first layer 11.

Then, as shown in FIG. 9A, the insulating body 51 is removed from the trench 70. Thereby, the gap 52 along the Z-axis direction is formed, which is provided between the first semiconductor region 10 and the first semiconductor film 1F. For example, the removal of the insulating body 51 may be performed after forming the first semiconductor region 10 including, for example, the first to sixth layers 11 to 16 as shown in FIG. 4F or may be performed after, for example, the chemical mechanical polishing of the sixth layer 16 and the sidewall region 50 including the insulating body 51 as shown in FIG. 4G.

Then, as shown in FIG. 9B, the second semiconductor layer (the semiconductor partial region 4) of the first conductivity type is formed on the surface 1aa of the first semiconductor film 1F, on the sixth layer 16 of the first semiconductor region 10, on the side surfaces of the first to sixth layers 11 to 16 inside the gap 52, and on the side surface of the first semiconductor layer inside the gap 52 under the film formation condition where the interior of the gap 52 is filled. Thus, the gap 52 is filled with the second semiconductor layer (the semiconductor partial region 4); and the sidewall region 50 that includes the second semiconductor layer (the semiconductor partial region 4) of the first conductivity type is formed as the semiconductor 53.

Then, as shown in FIG. 9C, the second semiconductor region 20 of the second conductivity type is formed inside the first semiconductor layer 1, e.g., in the second semiconductor layer (the semiconductor partial region 4), from the first surface 1a of the first semiconductor layer 1. The second semiconductor region 20 contacts the first semiconductor region 10 so as to be electrically connected to the first semiconductor region 10.

Thereafter, the first insulating film 60, the control electrode G, the second insulating film 61, the third semiconductor region 30, the first electrode D, and the second electrode S are formed according to the one example of the method for manufacturing the semiconductor device according to the first embodiment described above.

The sidewall region 50 may include the semiconductor 53 as in the semiconductor device according to the third embodiment. In the example, a part of the second semiconductor layer of the first conductivity type (i.e., a film for forming the semiconductor partial region 4) is used as the semiconductor 53. Accordingly, the semiconductor 53 is of the n-type, for example, which is the same as that of the first semiconductor layer 1. For example, the concentration of the n-type impurity of the semiconductor 53 is the same as the concentration of the n-type impurity of the second semiconductor layer (the film for forming the semiconductor partial region 4). By using the second semiconductor layer (the film for forming the semiconductor partial region 4) as the semiconductor 53, for example, an advantage can be obtained in that the sidewall region 50 that includes the semiconductor can be formed while suppressing an increase of the manufacturing processes.

Note that there is no necessity for the semiconductor 53 to have a conductivity type same as the conductivity type of the first semiconductor layer 1, e.g., the n-type. For example, the conductivity type of the semiconductor 53 may be the p-type which is the same as the conductivity type of the first semiconductor region 10. The first semiconductor region 10 includes at least the two layers of the first layer 11 and the second layer 12 that have different concentrations of the p-type impurity. Therefore, even if the conductivity type of the semiconductor 53 is the p-type, similarly to the first embodiment, the abrupt change of the capacitance can be suppressed. For example, it is also possible to further improve the breakdown voltage by adjusting the concentration of the n-type or p-type impurity of the semiconductor 53.

It is also possible to fill a gap between the first semiconductor region 10 and the first semiconductor layer 1 with an insulating body that is different from the insulating body 51 instead of the semiconductor 53 after removing the insulating body 51. In the case where the insulating body 51 is silicon oxide, the sidewall region 50 includes an insulating body that is different from silicon oxide such as, for example, silicon nitride, silicon oxynitride, a metal oxide, etc.

### Fourth Embodiment

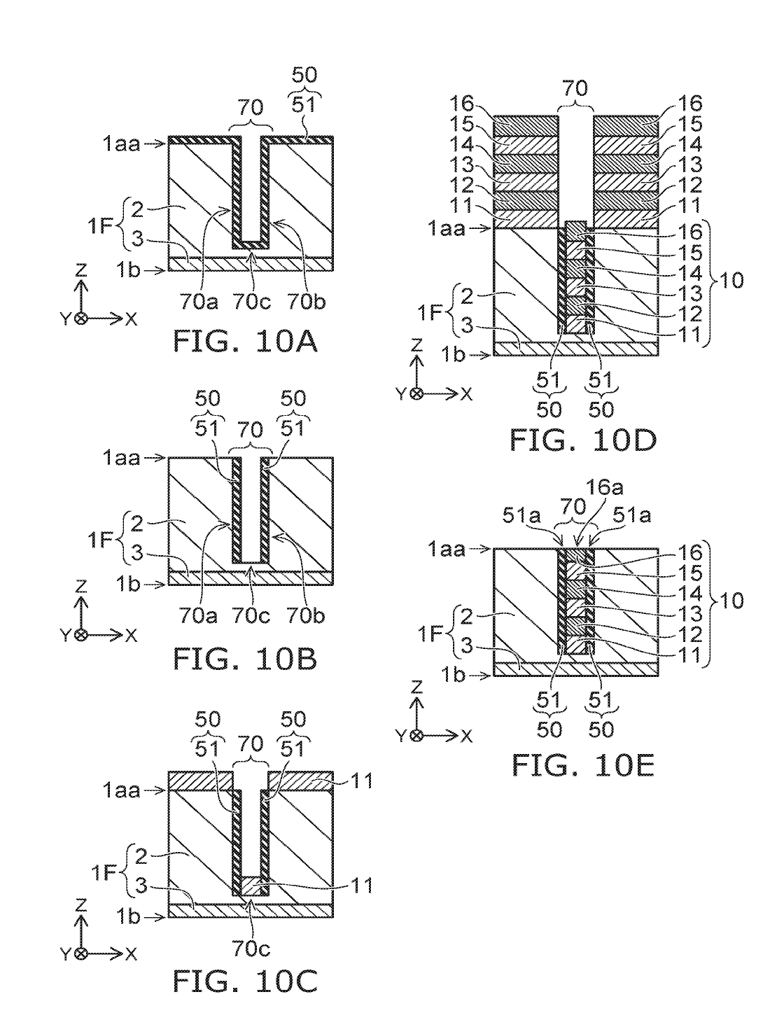

FIG. 10A to FIG. 10E are schematic cross-sectional views illustrating a method for manufacturing a semiconductor device according to a fourth embodiment.

The sidewall region 50 that includes the insulating body 51 is formed on the side surface 70a of the trench 70 according to the one example of the method for manufacturing the semiconductor device according to the first embodiment described above. In the example as shown in FIG. 10A, the sidewall region 50 that includes the insulating body 51 is formed on the surface 1aa of the first semiconductor film 1F, on the first side surface 70a of the trench 70, on the second side surface 70b of the trench 70, and on the bottom surface 70c of the trench 70. The insulating body 51 is, for example, silicon oxide. In the case where the insulating body 51 is, for example, silicon oxide, the insulating body 51 can be formed by thermal oxidation of the first semiconductor film 1F or by, for example, deposition of silicon oxide using CVD.

Then, as shown in FIG. 10B, the insulating body 51 that is on the surface 1aa of the first semiconductor film 1F and on the bottom surface 70c of the trench 70 is removed by, for example, performing anisotropic etching of the insulating body 51 using RIE. Thus, the insulating body 51 remains on the first side surface 70a of the trench 70 and on the second side surface 70b of the trench 70.

Subsequently as shown in FIG. 10C, the first layer 11 is formed on the bottom surface 70c of the trench 70 and on the surface 1aa of the first semiconductor film 1F by using the selective epitaxial growth. The first layer 11 is, for example, p-type Si. The p-type Si is formed by introducing a gas including, for example, Si and a gas including a p-type impurity, e.g., boron, into a processing chamber (not illustrated) of the film formation apparatus.

Then, as shown in FIG. 10D, the second layer 12 is formed on the first layer 11 by using the selective epitaxial growth. The second layer 12 is, for example, p-type Si. When forming the second layer 12, the flow rate of the gas including the p-type impurity, e.g., boron, inside the processing chamber (not illustrated) is different from that when forming the first layer 11. Thereby, the second layer 12 that is different in the p-type impurity concentration from the first layer 11 can be epitaxially grown selectively on the first layer 11. Then, the third to sixth layers 13 to 16 are formed similarly to the first layer 11 and the second layer 12 by using the selective epitaxial growth and by controlling the flow rate of the gas including, for example, boron so that the third to sixth layers 13 to 16 have the designed values of the p-type impurity concentrations. Thereby, the first semiconductor region 10 that includes at least the first layer 11 and the second layer 12 is formed inside the trench 70. In the example, the first to sixth layers 11 to 16 are formed also on the first surface 1aa of the first semiconductor film 1F.

Then, as shown in FIG. 10E, for example, the first to sixth layers 11 to 16 on the surface 1aa of the first semiconductor film 1F are chemically and mechanically polished. Thereby, the first to sixth layers 11 to 16 that are on the surface 1aa of the first semiconductor film 1F are removed. The surface of the first semiconductor film 1F is exposed at the surface 1aa of the first semiconductor film 1F. An upper surface 51a of the insulating body 51 and an upper surface 16a of the sixth layer 16 are exposed in the trench 70.

Thereafter, for example, the second semiconductor layer (the film for forming the semiconductor partial region 4), the second semiconductor region 20, the first insulating film 60, the control electrode G, the second insulating film 61, the third semiconductor region 30, the first electrode D, and the second electrode S are formed according to the one example of the method described above for manufacturing the semiconductor device in the first embodiment.

It should be noted that the method for manufacturing the semiconductor device according to the fourth embodiment can be used in combination with the second embodiment and in combination with the third embodiment.

In such a method for manufacturing the semiconductor device according to the fourth embodiment, for example, the PEP process used in the first embodiment can be omitted when forming the first semiconductor region 10 including at least the first layer 11 and the second layer 12. The process that can be omitted is, for example, the PEP process described with reference to FIG. 4C.

In the method for manufacturing the semiconductor device according to the fourth embodiment, for example, loading a wafer into and unloading it from the semiconductor manufacturing apparatuses such as the resist coating apparatus, the exposure apparatus, the development apparatus, the ashing apparatus, the cleaning apparatus, etc., can be omitted when forming the first semiconductor region 10. Thus, in the method for manufacturing the semiconductor device according to the fourth embodiment, throughput of the semiconductor device can be improved similarly to the first embodiment, the second embodiment, and the third embodiment.

Thus, according to the embodiments, a semiconductor device and a method for manufacturing the semiconductor device can be provided to suppress an abrupt change of the capacitance.

Hereinabove, the embodiments are described with reference to specific examples. However, the invention is not limited to these specific examples. For example, the materials of the first semiconductor layer 1 of the first conductivity type, the first semiconductor region 10 of the second conductivity type, the second semiconductor region 20 of the second conductivity type, the third semiconductor region 30 of the first conductivity type, the control electrode G, the first insulating film 60, the first electrode D, the second electrode S, the sidewall region 50, etc., are not limited to those recited in the embodiments.

Any two or more components of the specific examples also may be combined within the scope of technical feasibility of the invention as far as that includes the spirit of the invention.

All semiconductor devices and methods that can be actually performed by one skilled in the art under an appropriate design modification based on the semiconductor devices and the methods for manufacturing the semiconductor devices described above as the first to fourth embodiments of the invention also are within the scope of the invention as far as that includes the spirit of the invention.

Various modifications and alterations within the spirit of the invention will be readily apparent to those skilled in the art; and all such modifications and alterations should be seen as being within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first semiconductor layer of a first conductivity type having a first surface and a second surface, the first surface and the second surface crossing a first direction aligned with a direction from the second surface toward the first surface;
a first semiconductor region of a second conductivity type provided in the first semiconductor layer, the first semiconductor region including a first layer of the second conductivity type, and a second layer of the second conductivity type, a direction from the first layer toward the second layer being aligned with the first direction, and an impurity concentration of the second conductivity type in the second layer being different from an impurity concentration of the second conductivity type in the first layer;
a second semiconductor region of the second conductivity type electrically connected to the first semiconductor region, at least a portion of the second semiconductor region being provided at a position in the first direction between a position in the first direction of the first surface and a position in the first direction of the first semiconductor region;
a third semiconductor region of the first conductivity type, at least a portion of the third semiconductor region being provided at a position in the first direction between the position in the first direction of the first surface and the position in the first direction of the at least a portion of the second semiconductor region;
a control electrode;
a first insulating film provided between the control electrode and the second semiconductor region;
a first electrode electrically connected to the first semiconductor layer;
a second electrode electrically connected to the second semiconductor region and the third semiconductor region; and
a sidewall region provided between the first semiconductor region and the first semiconductor layer.

2. The device according to claim 1, wherein the sidewall region includes an insulating body.

3. The device according to claim 2, wherein the insulating body contacts the first layer and the second layer in a second direction crossing the first direction.

4. The device according to claim 1, wherein the sidewall region includes a semiconductor.

5. The device according to claim 4, wherein the semiconductor contacts the first layer and the second layer in a second direction crossing the first direction.

6. The device according to claim 1, further comprising a fourth semiconductor region of the second conductivity type,
the fourth semiconductor region being provided at a position in the first direction between the position of the first surface in the first direction and the position of the second semiconductor region in the first direction.

7. The device according to claim 6, wherein the fourth semiconductor region includes an impurity of the second conductivity type having a higher concentration than an impurity concentration of the second conductivity type in the second semiconductor region.

8. The device according to claim 1, wherein
the first semiconductor region extends in the first direction, and
the first semiconductor region contacts the second semiconductor region at an end on the first surface side.

9. The device according to claim 8, wherein the first semiconductor region contacts the first semiconductor layer at an end on the second surface side.

10. The device according to claim 9, wherein
the first layer of the first semiconductor region contacts the first semiconductor layer, and
the impurity concentration of the second conductivity type of the first layer is lower than the impurity concentration of the second conductivity type of the second layer.

11. The device according to claim 9, wherein
the first layer of the first semiconductor region contacts the first semiconductor layer, and
the impurity concentration of the second conductivity type of the first layer is higher than the impurity concentration of the second conductivity type of the second layer.

12. The device according to claim 1, wherein the first semiconductor layer includes a drift layer and a high-concentration layer, the drift layer including the first semiconductor region, and the high-concentration layer being provided between the first electrode and the drift layer and including an impurity of the first conductivity type having a higher concentration than an impurity concentration of the first conductivity type of the drift layer.

13. The device according to claim 1, wherein
the first semiconductor layer includes a semiconductor partial region of the first conductivity type, the semiconductor partial region being positioned between the position of the first surface in the first direction and a position of an interface between the first semiconductor region and the second semiconductor region in the first direction, and
the semiconductor partial region overlaps the second semiconductor region and the third semiconductor region in a direction crossing the first direction.

14. The device according to claim 13, wherein
the control electrode extends in a direction along the first surface to cover the semiconductor partial region, and
the first insulating film extends between the control electrode and the semiconductor partial region.

15. The device according to claim 1, further comprising a second insulating film covering the control electrode,
the second electrode extending in a direction along the first surface to cover the control electrode,
the second insulating film being positioned between the control electrode and the second electrode.

16. A semiconductor device, comprising:
a first semiconductor layer of a first conductivity type having a first surface and a second surface, the first surface and the second surface crossing a first direction aligned with a direction from the second surface toward the first surface;
a first semiconductor region of a second conductivity type provided in the first semiconductor layer, the first semiconductor region including a first layer of the second conductivity type, and a second layer of the second conductivity type, a direction from the first layer toward the second layer being aligned with the first direction, and an impurity concentration of the second conductivity type in the second layer being different from an impurity concentration of the second conductivity type in the first layer;
a second semiconductor region of the second conductivity type electrically connected to the first semiconductor region, at least a portion of the second semiconductor region being provided at a position in the first direction between a position in the first direction of the first surface and a position in the first direction of the first semiconductor region;
a third semiconductor region of the first conductivity type, at least a portion of the third semiconductor region being provided at a position in the first direction between the position in the first direction of the first surface and a position in the first direction of the at least a portion of the second semiconductor region;
a control electrode;
a first insulating film provided between the control electrode and the second semiconductor region;
a first electrode electrically connected to the first semiconductor layer; and
a second electrode electrically connected to the second semiconductor region and the third semiconductor region,
a gap being provided between the first semiconductor region and the first semiconductor layer in a direction crossing the first direction.

17. A method for manufacturing a semiconductor device, comprising:
forming a trench in a first surface of a first semiconductor film of a first conductivity type, the first semiconductor film having the first surface and a second surface, the first surface and the second surface crossing a first direction aligned with a direction from the second surface toward the first surface;
forming a sidewall region on a side surface of the trench, the sidewall region including an insulating body;
forming a first semiconductor region in the trench by using selective epitaxial growth, the first semiconductor region including a first layer of a second conductivity type and a second layer of a second conductivity type, an impurity concentration of the second conductivity type of the second layer being different from an impurity concentration of the second conductivity type of the first layer;
forming a second semiconductor region of the second conductivity type in the first semiconductor film from the first surface, the second semiconductor region being electrically connected to the first semiconductor region;
forming a first insulating film on the second semiconductor region;
forming a control electrode on the first insulating film;
forming a third semiconductor region of the first conductivity type on a portion of the second semiconductor region;
forming a first electrode electrically connected to the first semiconductor film; and
forming a second electrode electrically connected to the second semiconductor region and the third semiconductor region.

18. The method according to claim 17, further comprising:
removing the insulating body from the trench after forming the first semiconductor region in the trench.

19. The method according to claim 18, further comprising:
forming a semiconductor between the first layer and the first semiconductor film and between the second layer and the first semiconductor film after removing the insulating body from the trench.

20. The method according to claim 17, further comprising:
removing a portion of the first semiconductor region,
the sidewall region including an insulating body on a first side surface and a second side surface of the trench, and the forming the sidewall region including:
forming the insulating body on the first surface, on the first side surface of the trench, on the second side surface of the trench, and on a bottom surface of the trench; and
removing a portion of the insulating body on the first surface and a portion of the insulating body on the bottom surface, and
the forming of the first semiconductor region including:
forming the first semiconductor region in the trench and on the first surface of the first semiconductor film by using selective epitaxial growth, wherein
the removing of the portion of the first semiconductor region includes removing a portion of the first semiconductor region formed on the first surface.
